(19) United States
(12) Patent Application Publication
(10) Pub. No.: US 2026/0101618 A1
(43) Pub. Date: Apr. 9, 2026

(54) DISPLAY APPARATUS AND MANUFACTURING METHOD THEREOF

(71) Applicant: AUO Corporation, Hsinchu City (TW)

(72) Inventors: To-Cheng Fan, Hsinchu City (TW); Cheng-Chih Hsieh, Hsinchu City (TW); Ching-Yao Shih, Hsinchu City (TW); Wen-Wei Yang, Hsinchu City (TW); Kuan-Heng Lin, Hsinchu City (TW)

(73) Assignee: AUO Corporation, Hsinchu City (TW)

(21) Appl. No.: 18/953,068

(22) Filed: Nov. 20, 2024

(30) Foreign Application Priority Data
Oct. 7, 2024 (TW) 113138042

(51) Int. Cl. H01L 33/58; H01L 25/16; H01L 33/48; H01L 33/50

(52) U.S. Cl. CPC H10H 20/855; H10H 20/8506; H10H 20/8514; H10W 90/00; H10H 20/0361; H10H 20/0363

(57) ABSTRACT

A display apparatus includes a driving circuit substrate, light-emitting elements, a color conversion structure, an encapsulation layer, an opposite substrate and a bank layer. The light-emitting elements are disposed on the driving circuit substrate and are electrically connected to the driving circuit substrate. The color conversion structure covers a first light-emitting element of the light-emitting elements. The encapsulation layer is disposed on the driving circuit substrate. The opposite substrate is disposed opposite to the driving circuit substrate. The bank layer is disposed on the opposite substrate and is located between the opposite substrate and the encapsulation layer. There is a low refractive index material between a top surface of the color conversion structure and the opposing substrate of the low refractive index material is less than or equal to 1.2. In addition, a manufacturing method of the display apparatus is also provided.

### CROSS-REFERENCE TO RELATED APPLICATION

This application claims the priority benefit of Taiwan application serial no. 113138042, filed on Oct. 7, 2024. The entirety of the above-mentioned patent application is hereby incorporated by reference herein and made a part of this specification.

### BACKGROUND

### Technical Field

This disclosure relates to an optoelectronic device and its manufacturing method, and in particular to a display apparatus and its manufacturing method.

### Description of Related Art

A light-emitting diode display panel includes a driving circuit substrate and a plurality of light-emitting diode devices transferred onto the driving circuit substrate. Inheriting the characteristics of light-emitting diodes, the light-emitting diode display panel has advantages of power saving, high efficiency, high brightness, and fast response time. In addition, compared with an organic light-emitting diode display panel, the light-emitting diode display panel further has advantages of easy color adjustment, long light emission life, no image burn-in, etc. Therefore, the light-emitting diode display panel is considered as a display technology of the next generation. Each of the pixels of the light-emitting diode display panel includes a red sub-pixel, a green sub-pixel and a blue sub-pixels for respectively emitting red light, green light and blue light. However, the current utilization efficiency of the red sub-pixel light-emitting diode element is relatively low, which affects the performance of the light-emitting diode display panel.

### SUMMARY

This disclosure provides a display apparatus whose first light-emitting element has high current utilization efficiency.

This disclosure provides a method for manufacturing a display apparatus, which can produce a display apparatus with high current utilization efficiency.

A display apparatus of this disclosure includes a driving circuit substrate, a plurality of light-emitting elements, a color conversion structure, an encapsulation layer, an opposite substrate and a bank layer. The light-emitting elements are disposed on the driving circuit substrate and electrically connected to the driving circuit substrate. The light-emitting elements comprise a first light-emitting element. The color conversion structure covers the first light-emitting element. The encapsulation layer is disposed on the driving circuit substrate. The opposite substrate is disposed opposite the driving circuit substrate. The bank layer is disposed on the opposition substrate and located between the opposition substrate and the encapsulation layer. The color conversion structure has a top surface facing away from the driving circuit substrate. There is a low refractive index material between the top surface of the color conversion structure and the opposite substrate. A refractive index of the low refractive index material is less than or equal to 1.2

The manufacturing method of the display apparatus of this disclosure includes the following steps: providing a driving circuit substrate; transferring a plurality of light-emitting elements to the driving circuit substrate and electrically connecting the light-emitting elements to the driving circuit substrate, wherein the light-emitting elements comprise a first light-emitting element; forming a color conversion structure on the driving circuit substrate to cover the first light-emitting element, wherein the driving circuit substrate has a first region and a second region outside the first region, and the first light-emitting element and the color conversion structure is disposed in the first region of the driving circuit substrate; forming an encapsulation layer on the second region of the driving circuit substrate, wherein the encapsulation layer exposes the color conversion structure located in the first region; providing an opposite substrate; forming a bank layer on the opposite substrate, wherein the bank layer has openings, and an opposite element comprises the opposite substrate and the bank layer, and a light-emitting element substrate comprises the driving circuit substrate, the light-emitting elements, the color conversion structure and the encapsulation layer; and assembling the opposition element and the light-emitting element substrate, wherein the openings of the bank layer of the opposition element respectively correspond to the light-emitting elements of the light-emitting element substrate.

In an embodiment of this disclosure, the color conversion structure has a top surface facing away from the driving circuit substrate, there is a low refractive index material between the top surface of the color conversion structure and the opposite substrate, and a refractive index of the low refractive index material is less than or equal to 1.2.

In an embodiment of this disclosure, the color conversion structure directly covers the first light-emitting element.

In an embodiment of this disclosure, the refractive index of the low refractive index material is less than a refractive index of the color conversion structure and a refractive index of a first color filter pattern of the opposite substrate.

In an embodiment of this disclosure, the low refractive index material comprises a first air gap.

In an embodiment of this disclosure, the low refractive index material further exists between a side wall of the color conversion structure and a side wall of the bank layer.

In an embodiment of this disclosure, a distance between a side wall of the color conversion structure and a side wall of the bank layer in a direction parallel to the driving circuit substrate gradually changes as the distance moves away from the driving circuit substrate.

In an embodiment of this disclosure, a distance between an active layer of one of the light-emitting elements and the driving circuit substrate in a direction perpendicular to the driving circuit substrate is greater than a film thickness of the encapsulation layer in the direction.

In an embodiment of this disclosure, the encapsulation layer has a through hole, and the color conversion structure is disposed in the through hole.

In an embodiment of this disclosure, the encapsulation layer is in contact with a side wall of the color conversion structure.

### BRIEF DESCRIPTION OF THE DRAWINGS

FIG. 1A to FIG. 1G are schematic cross-sectional views of the manufacturing process of the display apparatus according to the first embodiment of the present disclosure.

FIG. 2 is a schematic cross-sectional view of the display apparatus of the second embodiment of the present disclosure.

FIG. 3 is a schematic cross-sectional view of the display apparatus of the third embodiment of the present disclosure.

FIG. 4 is a schematic cross-sectional view of the display apparatus of the fourth embodiment of the present disclosure.

FIG. 5 is a schematic cross-sectional view of the display apparatus of the fifth embodiment of the present disclosure.

FIG. 6 is a schematic cross-sectional view of the display apparatus of the sixth embodiment of the present disclosure.

### DESCRIPTION OF THE EMBODIMENTS

Reference will now be made in detail to exemplary embodiments provided in the disclosure, examples of which are illustrated in accompanying drawings. Wherever possible, identical reference numerals are used in the drawings and descriptions to refer to identical or similar parts.

It should be understood that when a device such as a layer, film, region or substrate is referred to as being “on” or “connected to” another device, it may be directly on or connected to another device, or intervening devices may also be present. In contrast, when a device is referred to as being “directly on” or “directly connected to” another device, there are no intervening devices present. As used herein, the term “connected” may refer to physical connection and/or electrical connection. Besides, if two devices are “electrically connected” or “coupled”, it is possible that other devices are present between these two devices.

The term “about,” “approximately,” or “substantially” as used herein is inclusive of the stated value and a mean within an acceptable range of deviation for the particular value as determined by people having ordinary skill in the art, considering the measurement in question and the error associated with measurement of the particular quantity (i.e., the limitations of the measurement system). For example, “about” may mean within one or more standard deviations, for example, ±30%, ±20%, ±10%, or ±5% of the stated value. Moreover, a relatively acceptable range of deviation or standard deviation may be chosen for the term “about,” “approximately,” or “substantially” as used herein based on optical properties, etching properties or other properties, instead of applying one standard deviation across all the properties.

Unless otherwise defined, all terms (including technical and scientific terms) used herein have the same meaning as commonly understood by people of ordinary skill in the art. It will be further understood that terms, such as those defined in the commonly used dictionaries, should be interpreted as having a meaning that is consistent with their meaning in the context of the relevant art and the invention and will not be interpreted in an idealized or overly formal sense unless expressly so defined herein.

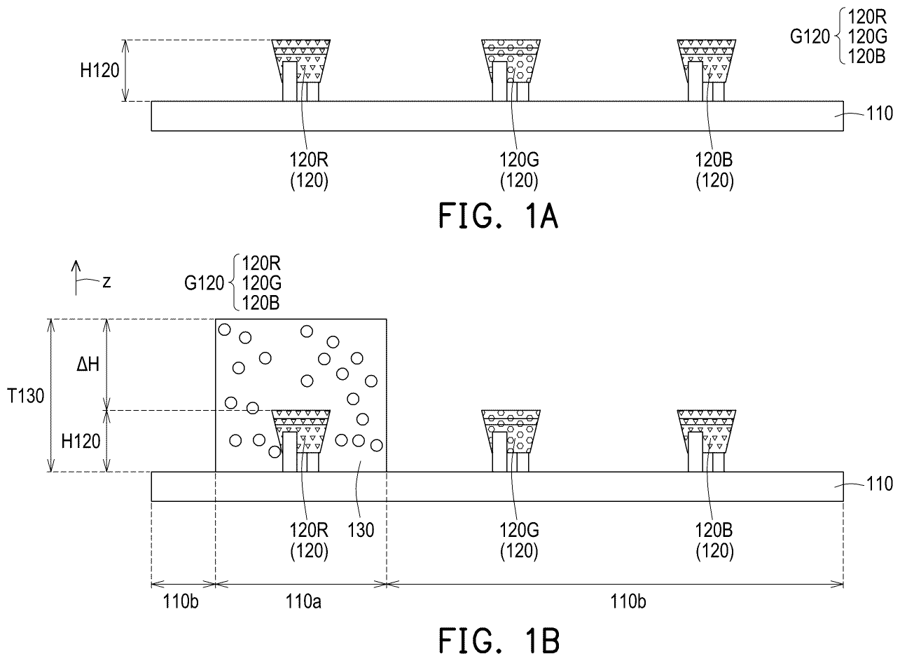

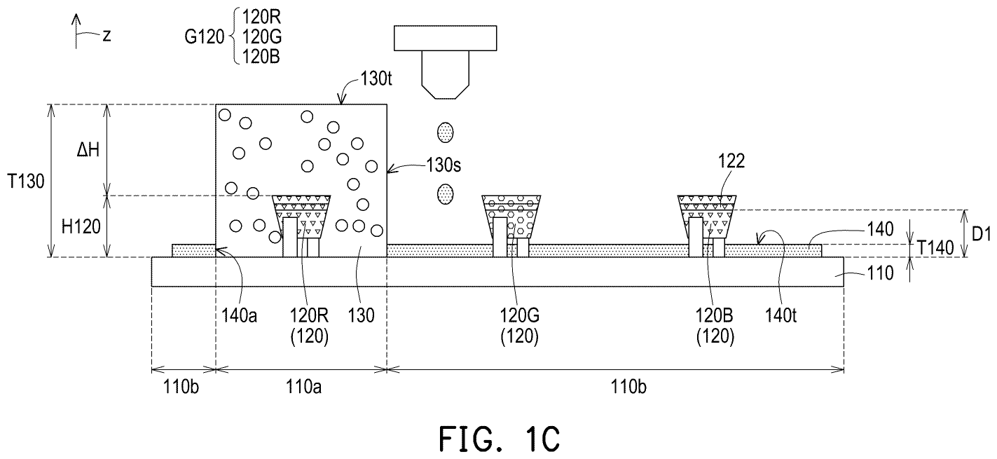

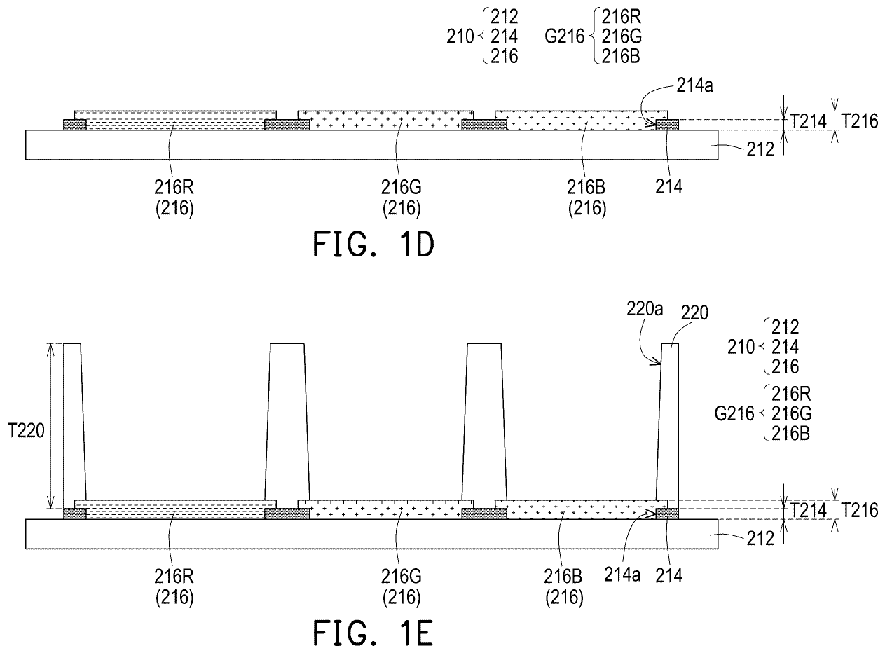

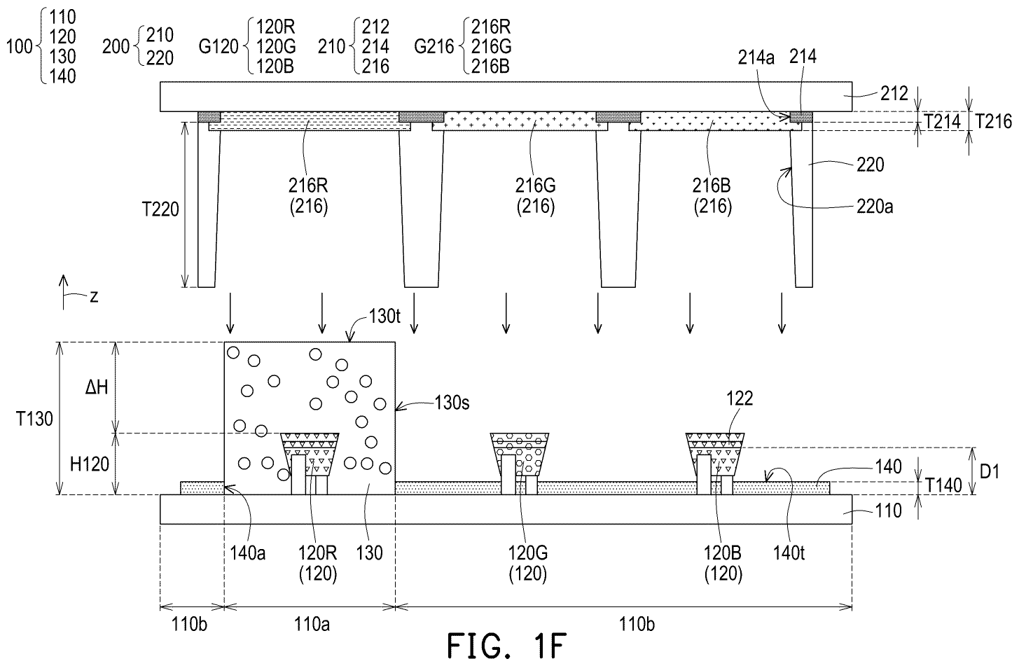

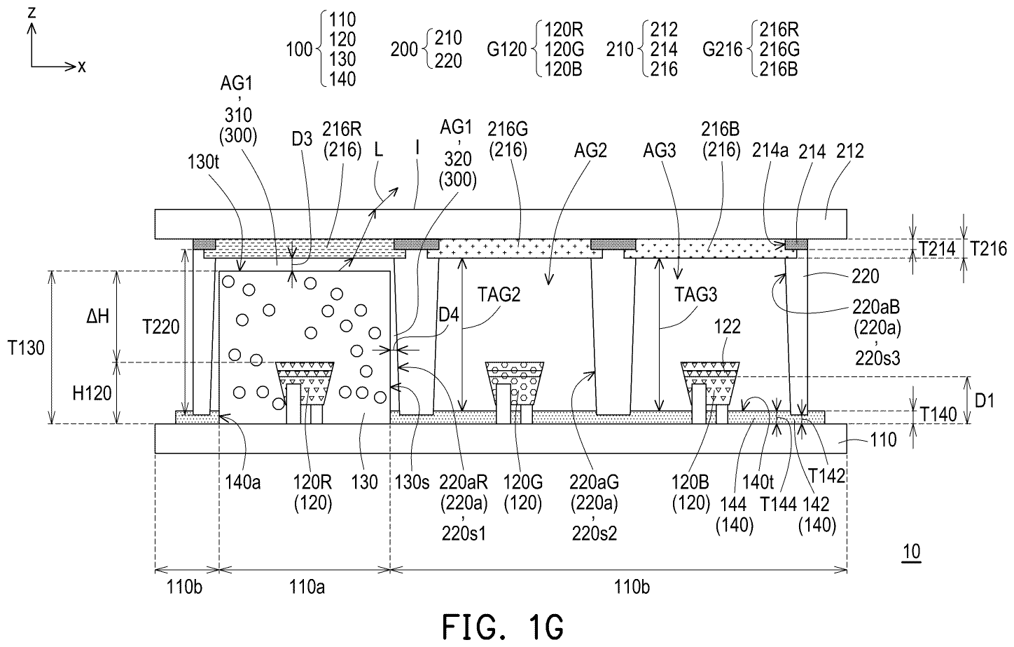

FIG. 1A to FIG. 1G are schematic cross-sectional views of the manufacturing process of the display apparatus according to the first embodiment of the present disclosure. Referring to FIG. 1A, first, a driving circuit substrate 110 is provided, which has a plurality of sub-pixel driving structures (not shown). In some embodiments, each of the sub-pixel driving structures may include a sub-pixel driving circuit (not shown) and a pad group (not shown) electrically connected to the sub-pixel driving circuit, wherein the pad group includes at least one bonding pad (not shown). For example, in some embodiments, each of the sub-pixel driving circuits may include a first transistor (not shown), a second transistor (not shown) and a capacitor (not shown), wherein a first terminal of the first transistor (not shown) is electrically connected to a corresponding data line (not shown), a control terminal of the first transistor is electrically connected to a corresponding scan line (not shown), a second terminal of the first transistor is electrically connected to the control terminal of the second transistor, a first terminal of the second transistor is electrically connected to a corresponding power line (not shown), and the capacitor is electrically connected to the second terminal of the first transistor and the first terminal of the second transistor, and the second terminal of the second transistor is electrically connected to a corresponding bonding pad group. However, this disclosure is not limited to thereto. In other embodiments, the sub-pixel driving circuit may be other forms of circuits.

Referring to FIG. 1A, next, light-emitting elements 120 are transferred to the driving circuit substrate 110, and the light-emitting elements 120 are electrically connected to the driving circuit substrate 110. The light-emitting elements 120 are respectively bonded to bonding pad groups (not shown) of the driving circuit substrate 110. In some embodiments, the light-emitting elements 120 may be divided into light-emitting element groups G120, and each of the light-emitting element group G120 corresponds to a pixel of the display apparatus. Each of the light-emitting element groups G120 may include a first light-emitting element 120R, a second light-emitting element 120G and a third light-emitting element 120B. For example, in some embodiments, the first light-emitting element 120R, the second light-emitting element 120G and the third light-emitting element 120B may be respectively light-emitting diode elements adapted to emitting a first color light, a second color light and a third color light, respectively. In some embodiments, the first color light, the second color light and the third color light are, for example, blue light, green light and blue light, but this disclosure is not limited thereto. Each of the light-emitting element 120 has a height H120. In some embodiments, the height H120 of the light-emitting element 120 may fall in the range of 5 μm to 9 μm. However, this disclosure is not limited to thereto. The height H120 of the light-emitting element 120 depends on the type of the light-emitting element 120.

Referring to FIG. 1B, next, a color conversion structure 130 is formed on the driving circuit substrate 110 to cover the first light-emitting element 120R. In some embodiments, the color conversion structure 130 may directly encapsulate the first light-emitting element 120R. The driving circuit substrate 110 has a first region 110a and a second region 110b. The first light-emitting element 120R and the color conversion structure 130 are disposed in the first region 110a of the driving circuit substrate 110. The second region 110b is located outside the first region 110a. The color conversion structure 130 can convert the first color light emitted by the first light-emitting element 120R into a fourth color light. For example, in some embodiments, the color conversion structure 130 may convert blue light emitted by the first light-emitting element 120R into red light. In some embodiments, photolithography may be optionally used to form the color conversion structure 130, but this disclosure is not limited to thereto. The color conversion structure 130 has a thickness T130 in a direction z perpendicular to the driving circuit substrate 110. In some embodiments, the thickness T130 of the color conversion structure 130 falls in the range of 14 μm to 21 μm, for example, but this disclosure is not limited to thereto. In some embodiments, the refractive index of the color conversion structure 130 falls in the range of 1.8 to 1.9, for example, but this disclosure is not limited to thereto. In some embodiments, the difference ΔH between the thickness T130 of the color conversion structure 130 and the height H120 of the light-emitting element 120 is, for example, in the range of 9 μm to 12 μm, but this disclosure is not limited to thereto.

Referring to FIG. 1C, next, an encapsulation layer 140 is formed on the second region 110b of the driving circuit substrate 110. In some embodiments, ink-jet printing (IJP) method may be optionally used to form the encapsulation layer 140, but this disclosure is not limited to thereto. The encapsulation layer 140 exposes the color conversion structure 130 disposed in the first region 110a. In some embodiments, the encapsulation layer 140 further exposes other light-emitting elements 120 that are not covered by the color conversion structure 130, such as the second light-emitting element 120G and the third light-emitting element 120B disposed in the second region 110b. In some embodiments, the encapsulation layer 140 has a through hole 140a, and the color conversion structure 130 is disposed in the through hole 140a. In some embodiments, the encapsulation layer 140 contacts a portion of the side wall 130s of the color conversion structure 130, and the encapsulation layer 140 exposes another portion of the side wall 130s of the color conversion structure 130 and the top surface 130t of the color conversion structure 130.

In some embodiments, a distance D1 between an active layer 122 of each of the light-emitting elements 120 and the driving circuit substrate 110 in a direction z perpendicular to the driving circuit substrate 110 is greater than a film thickness T140 of the encapsulation layer 140 in the direction z. That is to say, the top surface 140t of the encapsulation layer 140 facing away from the driving circuit substrate 110 is lower than the active layer (or a light-emitting layer) 122 of the light-emitting element 120. In some embodiments, the film thickness T140 of the encapsulation layer 140 falls in the range of 1 μm to 2 μm, for example, but this disclosure is not limited to thereto. In some embodiments, the refractive index of the encapsulation layer 140 falls in the range of 1.5 to 1.6, for example, but this disclosure is not limited to thereto.

Referring to FIG. 1D, next, an opposite substrate 210 is provided. In some embodiments, the opposite substrate 210 may include a transparent base 212, a light-shielding pattern layer 214 disposed on the transparent base 212, and color filter patterns 216 respectively located in openings 214a of the light-shielding pattern layer 214. In some embodiments, the color filter patterns 216 may be divided into color filter pattern groups 216. In detail, in some embodiments, each of the color filter pattern groups G216 may include a first color filter pattern 216R, a second color filter pattern 216G, and a third color filter pattern 216B. In some embodiments, the first color filter pattern 216R, the second color filter pattern 216G and the third color filter pattern 216B are, for example, a red filter pattern, a green filter pattern and a blue filter pattern respectively.

In some embodiments, the film thickness T214 of the light-shielding pattern layer 214 falls in the range of 1 μm to 1.5 μm, for example, but this disclosure is not limited thereto. In some embodiments, the refractive index of the light-shielding pattern layer 214 falls in the range of 1.5 to 1.6, for example, but this disclosure is not limited to thereto. In some embodiments, the thickness T216 of the color filter pattern 216 falls in the range of 2 μm to 2.5 μm, for example, but this disclosure is not limited to thereto. In some embodiments, the refractive index of color filter pattern 216 falls in the range of 1.5 to 1.7, for example, but this disclosure is not limited to thereto.

Referring to FIG. 1E, next, a bank layer 220 is formed on the opposite substrate 210, where the bank layer 220 has openings 220a. The openings 220a of the bank layer 220 are respectively located on the color filter patterns 216. In some embodiments, photolithography may be optionally used to form the bank layer 220, but this disclosure is not limited to thereto. In some embodiments, the thickness T220 of the bank layer 220 is, for example, in the range of 15 μm to 22 μm, but this disclosure is not limited thereto. In some embodiments, the refractive index of the bank layer 220 falls in the range of 1.5 to 1.6, for example, but this disclosure is not limited to thereto.

Referring to FIG. 1F, an opposite element 200 includes the opposition substrate 210 and the bank layer 220. A light-emitting element substrate 100 includes the driving circuit substrate 110, the light-emitting elements 120, the color conversion structure 130 and the encapsulation layer 140. Referring to FIG. 1F and FIG. 1G, next, the opposite element 200 and the light-emitting element substrate 100 are assembled to form a display apparatus 10.

Referring to FIG. 1G, openings 220a of the bank layer 220 of the opposite element 200 respectively correspond to the light-emitting elements 120 of the light-emitting element substrate 100. The opposite element 200 and the light-emitting element substrate 100 are connected to each other through the encapsulation layer 140. In some embodiments, a small portion of the bank layer 220 of the opposite element 200 may be trapped in the encapsulation layer 140 of the light-emitting element substrate 100, and the film thickness T142 of a first portion 142 of the encapsulation layer 140 that overlaps with a solid portion of the bank layer 220 may be smaller than the film thickness T144 of a second portion 144 of the encapsulation layer 140 located under the opening 220a of the bank layer 220. After the opposite element 200 and the light-emitting element substrate 100 are assembled, the light-emitting elements 120 of the light-emitting element substrate 100 are respectively located in the openings 220a of the bank layer 220, and the color conversion structure 130 is located in one of the opening 220a of the bank layer 220.

Referring to FIG. 1G, the display apparatus 10 includes the driving circuit substrate 110, the light-emitting elements 120, the color conversion structure 130, the encapsulation layer 140, the opposition substrate 210 and the bank layer 220. The light-emitting elements 120 are disposed on the driving circuit substrate 110 and are electrically connected to the driving circuit substrate 110. The light-emitting elements 120 includes a first light-emitting element 120R. The color conversion structure 130 covers the first light-emitting element 120R. The encapsulation layer 140 is disposed on the driving circuit substrate 110. The opposite substrate 210 is disposed opposite the driving circuit substrate 110. The bank layer 220 is disposed on the opposite substrate 210 and is located between the opposite substrate 210 and the encapsulation layer 140.

It is worth noting that the color conversion structure 130 has a top surface 130t facing away from the driving circuit substrate 110. There is a low refractive index material 300 between the top surface 130t of the color conversion structure 130 and the opposite substrate 210, and refractive index of the low refractive index material 300 is less than or equal to 1.2. The first light-emitting element 120R is used to emit the first color light (not shown). The first color light is converted into the fourth color light L by the color conversion structure 130. The fourth color light L is transmitted to the opposite substrate 210. Through the low refractive index material 300 located between the color conversion structure 130 and the opposite substrate 210, the fourth color light L can be deflected and incident on the opposite substrate 210 at a larger angle. Thereby, the proportion of total reflection of the fourth color light L at the interface I between the opposite substrate 210 and the external environment can be greatly reduced, thereby improving the light extraction efficiency of the fourth color light L (for example, red light). That is to say, the current utilization efficiency of the first light-emitting element 120R can be improved, wherein the current utilization efficiency refers to a ratio of the light intensity of the fourth color light L to the current of the first light-emitting element 120R. For example, in some embodiments, a ratio of the light intensity of the fourth color light L to the maximum current of the first light-emitting element 120R may be 9.967 cd/A, which is 96% higher than the current utilization efficiency of the conventional display apparatus.

In some embodiments, the refractive index of the low refractive index material 300 may be smaller than a refractive index of the color conversion structure 130 and a refractive index of a first color filter pattern 216R of the opposite substrate 210. In some embodiments, a portion 310 of the low refractive index material 300 is disposed between the top surface 130t of the color conversion structure 130 and the first color filter pattern 216R of the opposite substrate 210. In some embodiments, there is a distance D3 between the top surface 130t of the color conversion structure 130 and the first color filter pattern 216R of the opposite substrate 210. In some embodiments, the distance D3 is about 1 μm, but this disclosure is not limited to thereto.

In some embodiments, the openings 220a of the bank layer 220 include a first opening 220aR, a second opening 220aG, and a third opening 220aB, the first light-emitting element 120R, the second light-emitting element 120G, and the third light-emitting element 120B are respectively located in the first opening 220aR, the second opening 220aG and the third opening 220aB, another portion 320 of the low refractive index material 300 exists between a side wall 130s of the color conversion structure 130 and a side wall 220s1 of the bank layer 220 defining the first opening 220aR. In some embodiments, a distance D4 between the side wall 130s of the color conversion structure 130 and the side wall 220s1 of the bank layer 220 gradually changes away from the driving circuit substrate 110 in a direction x parallel to the driving circuit substrate 110. For example, in some embodiments, the distance D4 may gradually become smaller as it moves away from the driving circuit substrate 110, but this disclosure is not limited thereto. In some embodiments, the distance D4 falls within the range of 1 μm to 2 μm, for example, but this disclosure is not limited to thereto.

In some embodiments, the low refractive index material 300 between the color conversion structure 130 and the first color filter pattern 216R of the opposite substrate 210 includes a first air gap AG1. In some embodiments, a second air gap AG2 further exists in a space surrounded by the second color filter pattern 216G, a side wall 220s2 defining the second opening 220aG of the bank layer 220, the second light-emitting element 120G and the encapsulation layer 140. In some embodiments, the maximum thickness TAG2 of the second air gap AG2 is about 19 μm, but this disclosure is not limited to thereto. In some embodiments, a third air gap AG3 further exists in a space surrounded by the third color filter pattern 216B, a side wall 220s3 defining the third opening 220aB of the bank layer 220, the third light-emitting element 120B and the encapsulation layer 140. In some embodiments, the maximum thickness TAG3 of the third air gap AG3 is about 19 μm, but this disclosure is not limited to thereto.

The display apparatus 10 according to one embodiment of this disclosure can significantly improve the light extraction efficiency of the fourth color light L (for example, red light). The display apparatus 10 has a simple manufacturing process and low production complexity. The display apparatus 10 and its manufacturing method according to an embodiment of this disclosure have at least one of the following advantages:
(1) Using the ink-jet printing (IJP) method to form the encapsulation layer 140 on the driving circuit substrate 110 can accurately control the film thickness T140 of the encapsulation layer 140, whereby the air gaps (first air gapAG1, second air gapAG2 and/or third air gapAG3) can be controlled and more uniform;
(2) The encapsulation layer 140 covers the bonding pads of the light-emitting element 120, the bonding pad group of the driving circuit substrate 110, and an eutectic layer formed by the above two. That is to say, the encapsulation layer 140 covers the areas prone to problems in the reliability test, so as to achieve protective effect;
(3) After the opposite element 200 is assembled with the light-emitting element substrate 100, the active layer 122 of the second light-emitting element 120G and the active layer 122 of the third light-emitting element 120B are located in the second air gapAG2 and the third air gapAG3 respectively, and will not be covered by the encapsulation layer 140, thereby improving the light extraction efficiency of the second color light emitted by the second light-emitting element 120G and the light extraction efficiency of the third color light emitted by the third light-emitting element 120B.

In the following embodiment, the reference numerals and part of the description of the foregoing embodiment are applied, where the same reference numerals are used to indicate the same or similar components, and descriptions of the same technical contents are omitted. Reference may be made to the foregoing embodiment for the omitted descriptions, which will not be repeated in following embodiment.

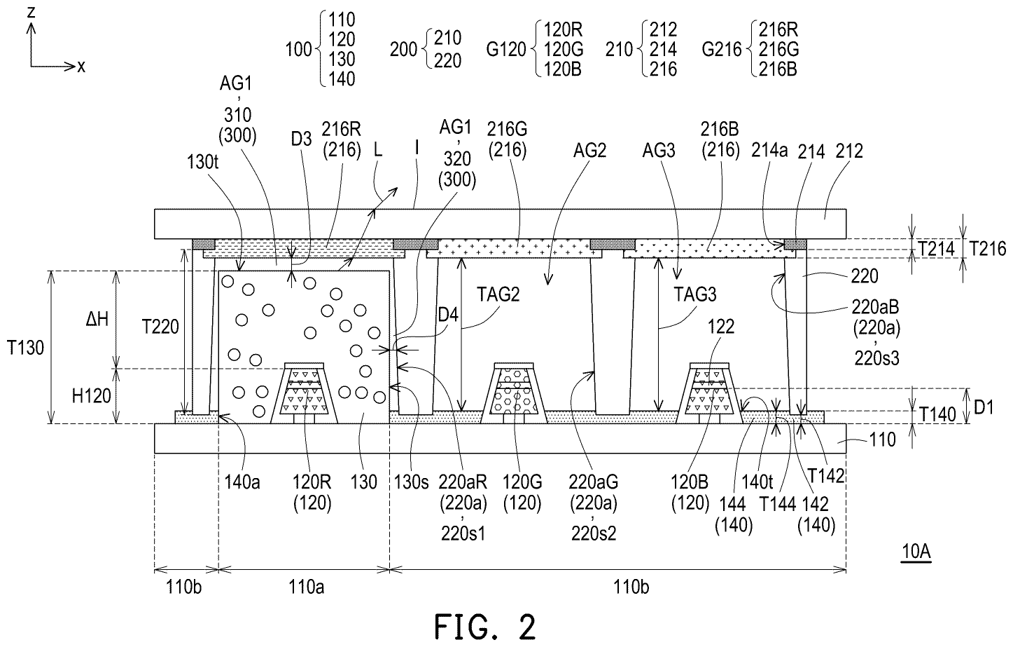

FIG. 2 is a schematic cross-sectional view of the display apparatus of the second embodiment of the present disclosure. The display apparatus 10A of FIG. 2 is similar to the display apparatus 10 of FIG. 1G. The difference between the two is that the light-emitting element 120 of the display apparatus 10A of FIG. 2 is different from the light-emitting element 120 of the display apparatus 10 of FIG. 1G. Specifically, the light-emitting element 120 of the display apparatus 10 in FIG. 1G is a flip chip, and the light-emitting element 120 of the display apparatus 10A in FIG. 2 is a vertical chip.

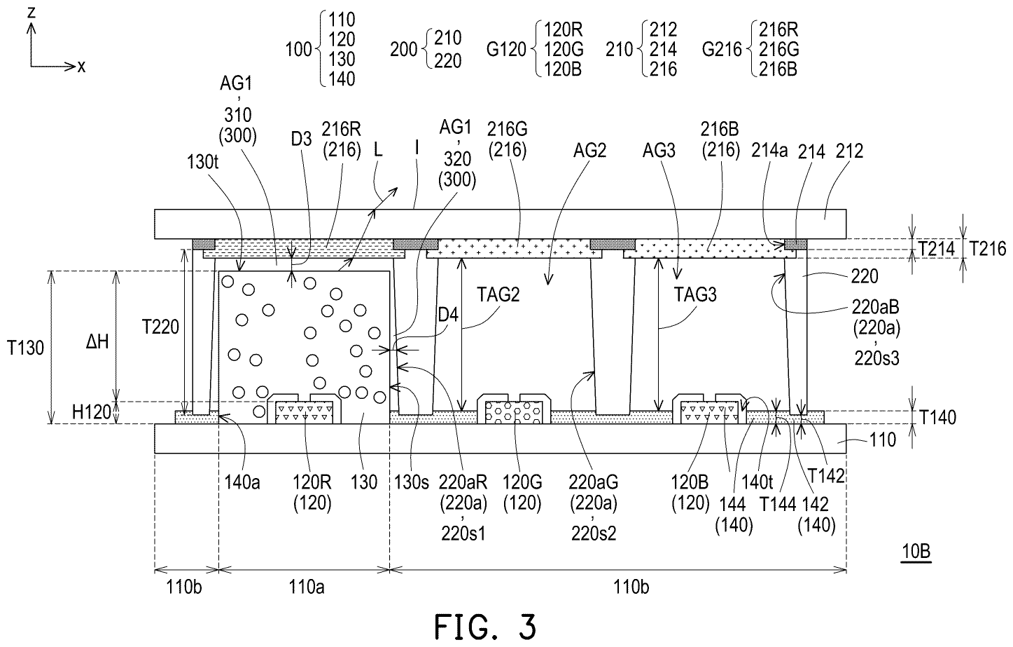

FIG. 3 is a schematic cross-sectional view of the display apparatus of the third embodiment of the present disclosure. The display apparatus 10B of FIG. 3 is similar to the display apparatus 10 of FIG. 1G. The difference between the two is that the light-emitting element 120 of the display apparatus 10B of FIG. 3 is different from the light-emitting element 120 of the display apparatus 10 of FIG. 1G. Specifically, the light-emitting element 120 of the display apparatus 10 in FIG. 1G is a flip chip, and the light-emitting element 120 of the display apparatus 10A in FIG. 3 is a lateral chip.

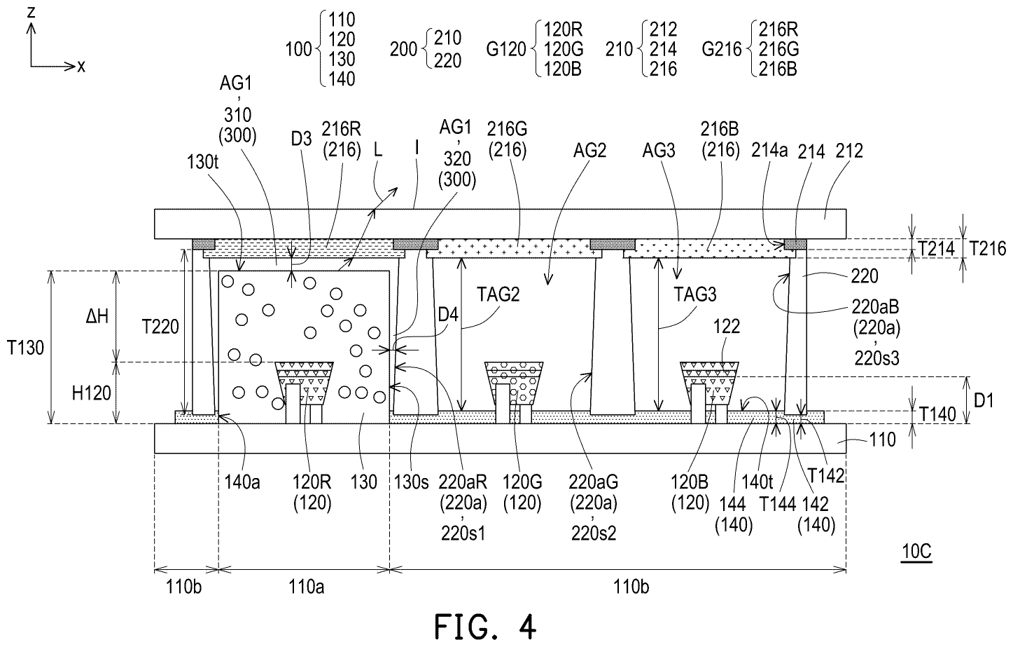

FIG. 4 is a schematic cross-sectional view of the display apparatus of the fourth embodiment of the present disclosure. The display apparatus 10C of FIG. 4 is similar to the display apparatus 10 of FIG. 1G. The difference between the two is that in the embodiment of FIG. 4, the distance D4 gradually becomes larger as it moves away from the driving circuit substrate 110.

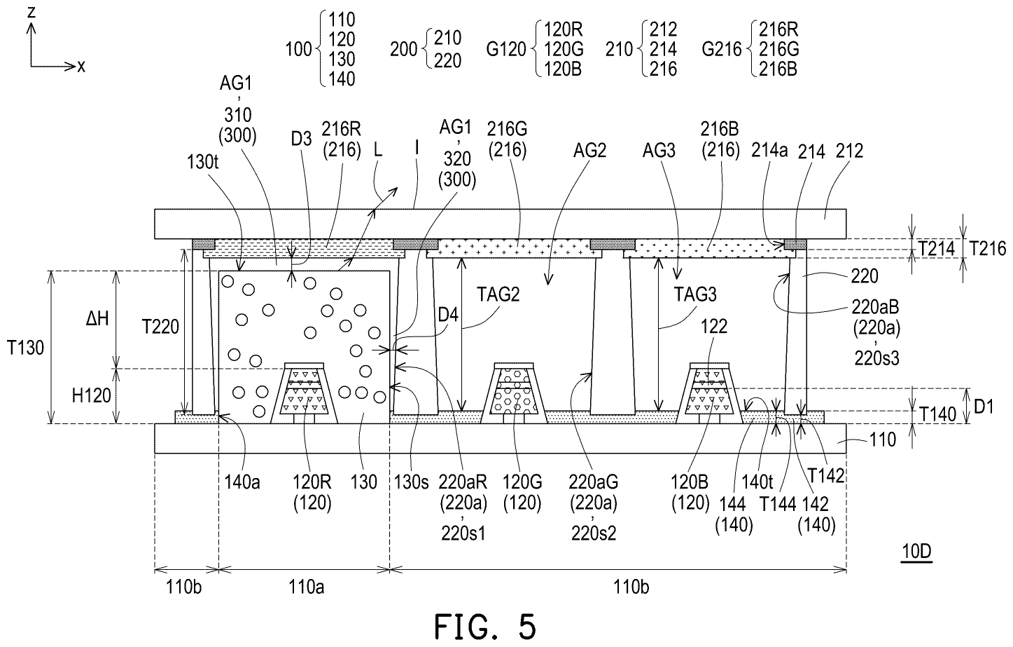

FIG. 5 is a schematic cross-sectional view of the display apparatus of the fifth embodiment of the present disclosure. The display apparatus 10D of FIG. 5 is similar to the display apparatus 10A of FIG. 2. The difference between the two is that in the embodiment of FIG. 5, the distance D4 gradually becomes larger as it moves away from the driving circuit substrate 110.

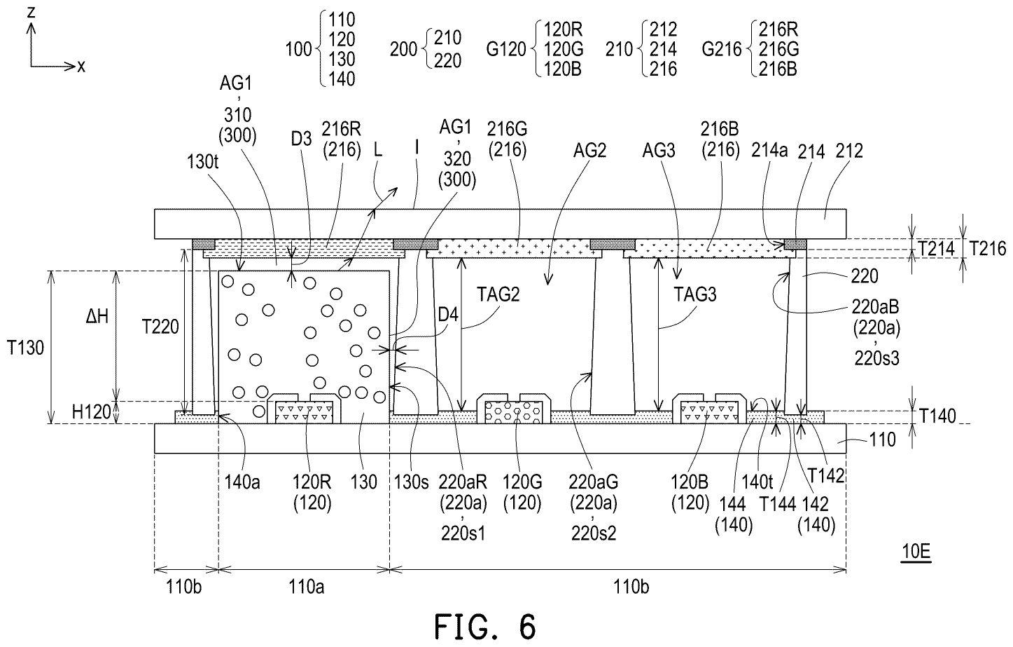

FIG. 6 is a schematic cross-sectional view of the display apparatus of the sixth embodiment of the present disclosure. The display apparatus 10E of FIG. 6 is similar to the display apparatus 10B of FIG. 3. The difference between the two is that in the embodiment of FIG. 6, the distance D4 gradually becomes larger as it moves away from the driving circuit substrate 110.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A display apparatus comprising:
a driving circuit substrate;
a plurality of light-emitting elements disposed on the driving circuit substrate and electrically connected to the driving circuit substrate;
a color conversion structure, wherein the light-emitting elements comprise a first light-emitting element, and the color conversion structure covers the first light-emitting element;
an encapsulation layer, disposed on the driving circuit substrate;
an opposite substrate disposed opposite the driving circuit substrate; and
a bank layer, disposed on the opposition substrate and located between the opposition substrate and the encapsulation layer;
the color conversion structure has a top surface facing away from the driving circuit substrate, there is a low refractive index material between the top surface of the color conversion structure and the opposite substrate, and a refractive index of the low refractive index material is less than or equal to 1.2.

2. The display apparatus according to claim 1, wherein the color conversion structure directly covers the first light-emitting element.

3. The display apparatus according to claim 1, wherein the refractive index of the low refractive index material is less than a refractive index of the color conversion structure and a refractive index of a first color filter pattern of the opposite substrate.

4. The display apparatus according to claim 1, wherein the low refractive index material comprises a first air gap.

5. The display apparatus according to claim 1, wherein the low refractive index material further exists between a side wall of the color conversion structure and a side wall of the bank layer.

6. The display apparatus according to claim 1, wherein a distance between a side wall of the color conversion structure and a side wall of the bank layer in a direction parallel to the driving circuit substrate gradually changes as the distance moves away from the driving circuit substrate.

7. The display apparatus according to claim 1, wherein a distance between an active layer of one of the light-emitting elements and the driving circuit substrate in a direction perpendicular to the driving circuit substrate is greater than a film thickness of the encapsulation layer in the direction.

8. The display apparatus according to claim 1, wherein the encapsulation layer has a through hole, and the color conversion structure is disposed in the through hole.

9. The display apparatus according to claim 1, wherein the encapsulation layer is in contact with a side wall of the color conversion structure.

10. A manufacturing method of a display apparatus comprising:
providing a driving circuit substrate;
transferring a plurality of light-emitting elements to the driving circuit substrate and electrically connecting the light-emitting elements to the driving circuit substrate, wherein the light-emitting elements comprise a first light-emitting element;
forming a color conversion structure on the driving circuit substrate to cover the first light-emitting element, wherein the driving circuit substrate has a first region and a second region outside the first region, and the first light-emitting element and the color conversion structure is disposed in the first region of the driving circuit substrate;
forming an encapsulation layer on the second region of the driving circuit substrate, wherein the encapsulation layer exposes the color conversion structure located in the first region;
providing an opposite substrate;
forming a bank layer on the opposite substrate, wherein the bank layer has openings, and an opposite element comprises the opposite substrate and the bank layer, and a light-emitting element substrate comprises the driving circuit substrate, the light-emitting elements, the color conversion structure and the encapsulation layer; and
assembling the opposition element and the light-emitting element substrate, wherein the openings of the bank layer of the opposition element respectively correspond to the light-emitting elements of the light-emitting element substrate.

11. The manufacturing method of the display apparatus according to claim 10, wherein the color conversion structure directly covers the first light-emitting element.

12. The manufacturing method of the display apparatus according to claim 10, wherein the color conversion structure has a top surface facing away from the driving circuit substrate, there is a low refractive index material between the top surface of the color conversion structure and the opposite substrate, and a refractive index of the low refractive index material is less than or equal to 1.2.

13. The manufacturing method of the display apparatus according to claim 12, wherein the refractive index of the low refractive index material is less than a refractive index of the color conversion structure and a refractive index of a first color filter pattern of the opposite substrate.

14. The manufacturing method of the display apparatus according to claim 12, wherein the low refractive index material comprises a first air gap.

15. The manufacturing method of the display apparatus according to claim 12, wherein the low refractive index material further exists between a side wall of the color conversion structure and a side wall of the bank layer.

16. The manufacturing method of the display apparatus according to claim 10, wherein a distance between a side wall of the color conversion structure and a side wall of the bank layer in a direction parallel to the driving circuit substrate gradually changes as the distance moves away from the driving circuit substrate.

17. The manufacturing method of the display apparatus according to claim 10, wherein a distance between an active layer of one of the light-emitting elements and the driving circuit substrate in a direction perpendicular to the driving circuit substrate is greater than a film thickness of the encapsulation layer in the direction.

18. The manufacturing method of the display apparatus according to claim 10, wherein the encapsulation layer has a through hole, and the color conversion structure is disposed in the through hole.

19. The manufacturing method of the display apparatus according to claim 10, wherein the encapsulation layer is in contact with a side wall of the color conversion structure.
